(19) United States
(12) Patent Application Publication
(10) Pub. No.: US 2010/0261106 A1
(43) Pub. Date: Oct. 14, 2010

(54) MEASUREMENT APPARATUS, EXPOSURE APPARATUS, AND DEVICE FABRICATION METHOD

(75) Inventor: Takenobu Kobayashi, Utsunomiya-shi (JP)

Correspondence Address: ROSSI, KIMMS & McDOWELL LLP., 20609 Gordon Park Square, Suite 150, Ashburn, VA, 20147, US

(73) Assignee: CANON KABUSHIKI KAISHA, Tokyo (JP)

(21) Appl. No.: 12/756,150

(22) Filed: Apr. 7, 2010

(30) Foreign Application Priority Data
Apr. 8, 2009 (JP) 2009-094366

(51) Int. Cl. G03F 7/20; G01B 1/00; G03B 27/52

(52) U.S. Cl. 430/30; 702/94; 355/72

(57) ABSTRACT

The present invention provides a measurement apparatus which includes a scale and a sensor one of which is attached on a target object, and measures a position of the target object by reading the scale by the sensor, the apparatus including a detection unit configured to detect a shift amount of the scale from a reference position, and a calculation unit configured to correct, the position of the target object measured by reading the scale by the sensor, based on the shift amount of the scale from the reference position, which is detected by the detection unit.

### BACKGROUND OF THE INVENTION

1. Field of the Invention

The present invention relates to a measurement apparatus, an exposure apparatus, and a device fabrication method.

2. Description of the Related Art

An exposure apparatus is employed to fabricate micropatterned semiconductor devices such as a semiconductor memory and a logic circuit using photolithography. The exposure apparatus projects and transfers a pattern formed on a reticle (mask) onto a substrate such as a wafer via a projection optical system. The exposure apparatus holds the wafer on a stage via a chuck and repeats the pattern transfer while changing the exposure target position on the wafer by moving the wafer together with the stage.

A laser interferometer which projects laser light onto a mirror fixed on a stage is commonly used for measurement (length measurement) of the relative position of a wafer (the stage which holds it). However, a laser interferometer has a long measurement optical path length (measurement space distance), so an environmental change such as a change in temperature, humidity, or atmospheric pressure causes distance measurement errors.

On the other hand, Japanese Patent Laid-Open No. 7-270122 proposes a measurement apparatus (displacement measurement apparatus) which exploits the principle of interference by a diffraction grating as an alternative to a laser interferometer. Because this measurement apparatus has a short measurement space distance, it is less subject to an environmental change and therefore can stably measure the relative position of a wafer. More specifically, the measurement apparatus mainly includes a head (sensor) and diffraction grating (scale), and the sensor is attached on, for example, a stage, and the scale is attached on, for example, a reference frame in an exposure apparatus. In this case, a large scale is required to measure the overall moving range of a stage, but it is very difficult to manufacture a high-precision diffraction grating over a wide range. Under the circumstance, Japanese Patent Laid-Open No. 2007-318119 proposes a method of using a plurality of small scales having a total area equal to the area of a large scale. In addition, such a measurement apparatus generally uses a chuck scheme such as chuck by vacuum suction or magnetic attraction to facilitate attachment or detachment of a scale and to reduce flexure of the scale surface.

Unfortunately, it is very difficult to precisely position and fix the plurality of scales with respect to the reference frame. Furthermore, when an chuck scheme is used, the scale attachment position changes for each chuck, and this leads to a high probability that the coordinates and running characteristics of the stage will change due to erroneous measurement of the stage position.

### SUMMARY OF THE INVENTION

The present invention can provide a technique which can measure the position of a target object (for example, a stage) with high accuracy even when the position of a scale shifts from a reference position.

According to one aspect of the present invention, there is provided a measurement apparatus which includes a scale and a sensor one of which is attached on a target object, and measures a position of the target object by reading the scale by the sensor, the apparatus including a detection unit configured to detect a shift amount of the scale from a reference position, and a calculation unit configured to correct, the position of the target object measured by reading the scale by the sensor, based on the shift amount of the scale from the reference position, which is detected by the detection unit.

Further features of the present invention will become apparent from the following description of exemplary embodiments with reference to the attached drawings.

### BRIEF DESCRIPTION OF THE DRAWINGS

FIG. 1 is a schematic view showing the arrangement of an exposure apparatus according to one aspect of the present invention.

FIG. 2 is a plan view of scales which constitute the measurement apparatus according to one aspect of the present invention when viewed from the Z-axis direction.

FIG. 3 is a plan view of sensors which constitute the measurement apparatus according to one aspect of the present invention when viewed from the Z-axis direction.

FIGS. 4A to 4C are views for explaining the arrangement of a displacement detection apparatus applicable to the measurement apparatus according to one aspect of the present invention.

FIG. 5 is an enlarged sectional view showing the arrangement of the measurement apparatus according to one aspect of the present invention.

FIG. 6 is a view illustrating one example of the arrangement of a reference mark.

FIG. 7 is a view for explaining correction of the position of a wafer stage, measured by reading a scale by a sensor, by a calculation unit of the measurement apparatus.

FIG. 8 is a view showing the moving track of the wafer stage.

FIG. 9 is a flowchart for explaining an example of the operation of the exposure apparatus shown in FIG. 1.

FIG. 10 is a flowchart for explaining another example of the operation of the exposure apparatus shown in FIG. 1.

FIGS. 11A and 11B are views showing another arrangement of the measurement apparatus according to one aspect of the present invention.

FIGS. 12A to 12C are views showing still another arrangement of the measurement apparatus according to one aspect of the present invention.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

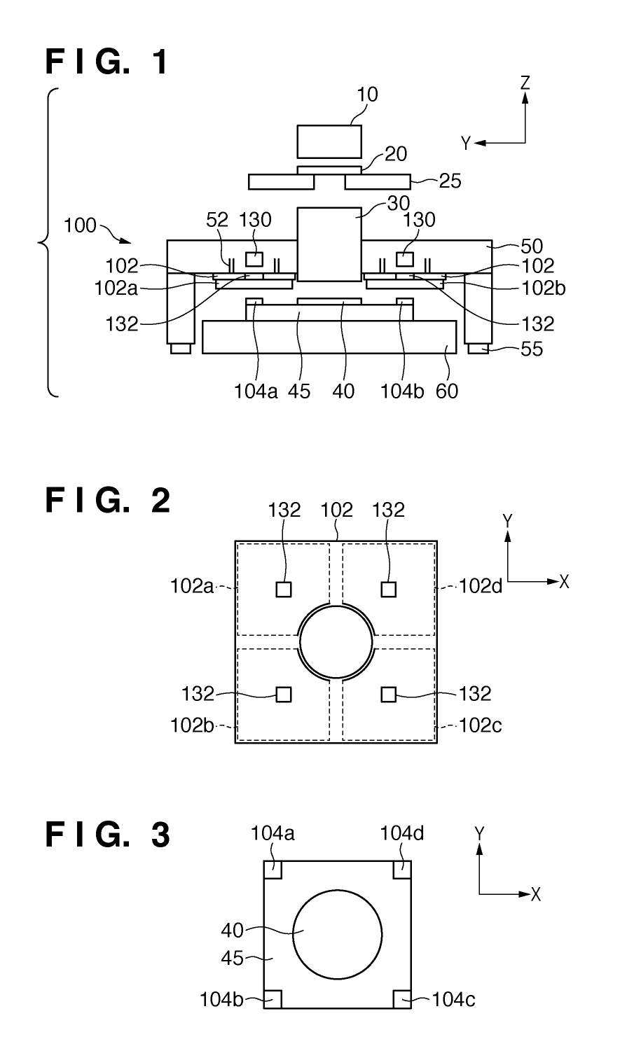

An exposure apparatus 1 according to one aspect of the present invention will be explained with reference to FIG. 1. In this embodiment, the exposure apparatus 1 is a projection exposure apparatus which transfers the pattern of a reticle 20 onto a wafer 40 by the step & scan scheme. However, the exposure apparatus 1 can also adopt the step & repeat scheme or another exposure scheme. The exposure apparatus 1 includes an illumination optical system 10, reticle stage 25, projection optical system 30, wafer stage 45, reference frame 50, active mount 55, stage surface plate 60, control unit 70, and measurement apparatus 100.

The illumination optical system 10 illuminates the reticle 20 held by the reticle stage 25 which can move in the Y-axis direction with light from a light source. A pattern formed on the reticle 20 is projected onto the wafer 40 via the projection optical system 30 supported by the reference frame 50 serving as a structure which faces the wafer stage 45. The active mount 55 supports the reference frame 50 and insulates vibration from the floor. The stage surface plate 60 supports the wafer stage 45 as a target object for the measurement apparatus 100. The wafer stage 45 holds the wafer 40 and can move in the X- and Y-axis directions. The control unit 70 controls the whole (operation) of the exposure apparatus 1. The control unit 70 controls, for example, the position of the wafer stage 45 so as to form the pattern of the reticle 20 in a predetermined region on the wafer 40. The control unit 70 also functions as a storage unit 72 and calculation unit 74 for the measurement apparatus 100, as will be described later.

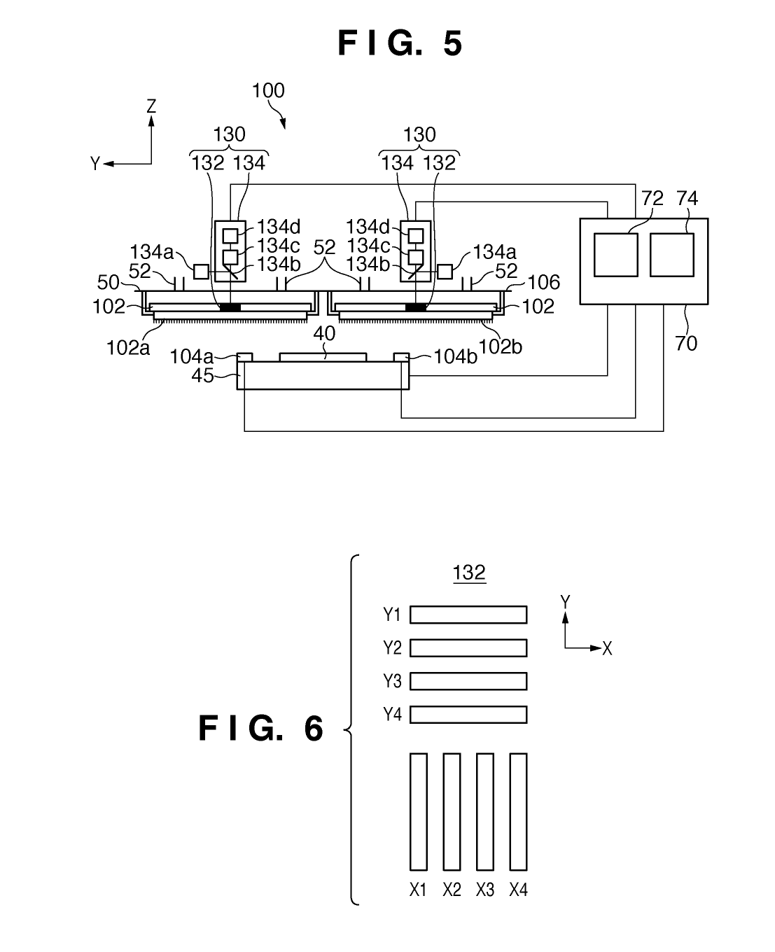

The measurement apparatus 100 includes four scales 102a to 102d mounted on a scale plate 102, as shown in FIG. 2, and four sensors 104a to 104d attached on the wafer stage 45, as shown in FIG. 3. In this embodiment, the scale plate 102 which mounts the four scales 102a to 102d is chucked by vacuum suction by the reference frame 50 by lowering the pressures in a plurality of grooves 52 formed in the reference frame 50. However, the plurality of grooves 52 may be substituted by a magnetic chuck mechanism to chuck by magnetic attraction the scale plate 102 which mounts the four scales 102a to 102d. In this manner, the scale plate 102 which mounts the four scales 102a to 102d is detachably attached on the reference frame 50. Also, the four scales 102a to 102d and four sensors 104a to 104d are arranged such that at least one sensor can read one scale within the moving range of the wafer stage 45. Hence, the measurement apparatus 100 can measure the position of the wafer stage 45 with respect to the reference frame 50 in two axial directions (the X- and Y-axis directions) by reading the scales 102a to 102d by the sensors 104a to 104d. Note that the measurement apparatus 100 also includes a holding mechanism 106 which holds the scales 102a to 102d when chuck (chuck by vacuum suction or magnetic attraction) of the scale plate 102 which mounts the scales 102a to 102d stops (see FIG. 5).

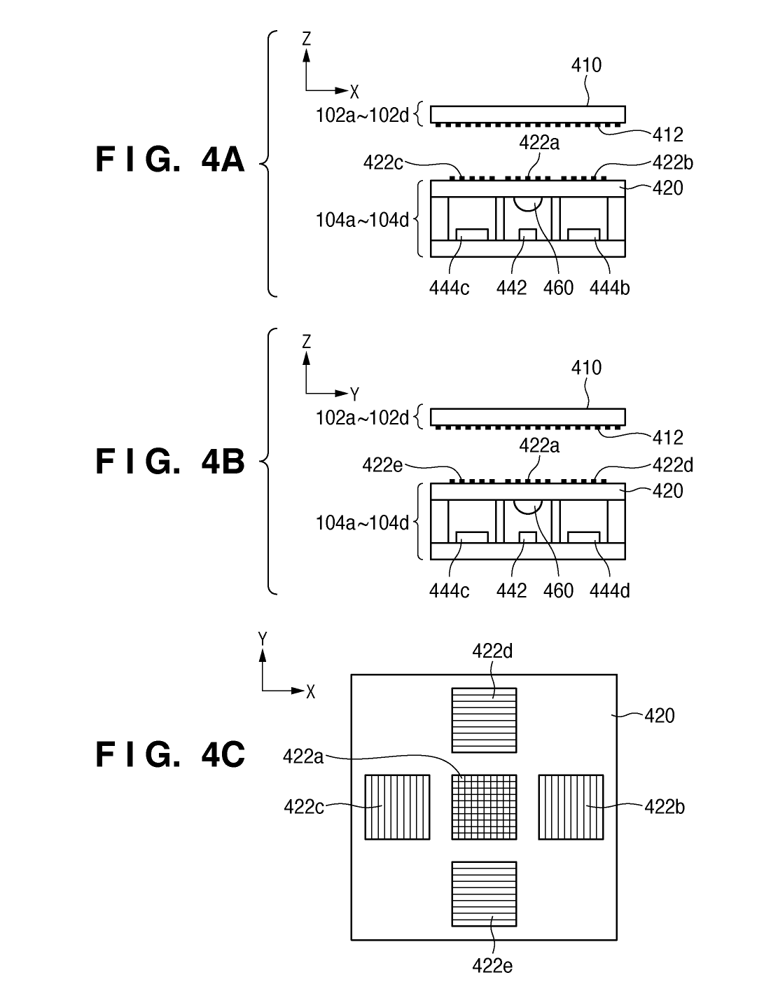

One example of the detailed arrangement of the measurement apparatus 100 will be explained herein. An optical displacement detection apparatus is applicable to the measurement apparatus 100, as shown in FIGS. 4A to 4C. FIG. 4A is a sectional view of the displacement detection apparatus taken along the X-axis direction, FIG. 4B is a sectional view of the displacement detection apparatus taken along the Y-axis direction, and FIG. 4C is a plan view of a diffraction grating plate 420 which constitutes the displacement detection apparatus when viewed from the Z-axis direction. Both a diffraction grating 412 formed on a diffraction grating plate 410, and a diffraction grating 422a formed on the diffraction grating plate 420 diffract light beams in two orthogonal axial directions. The diffraction grating plate 420 also includes diffraction gratings 422b and 422c aligned in the X-axis direction and diffraction gratings 422d and 422e aligned in the Y-axis direction with the diffraction grating 422a at their center. A light source 442 and light-receiving devices 444b to 444e arranged on a circuit board made of, e.g., glass epoxy resin constitute a sensor. The displacement detection apparatus can detect a displacement of a target object in two axial directions by irradiating the diffraction grating plates 410 and 420 with light from the light source 442 via a lens 460, and receiving, by the light-receiving devices 444b to 444e, the light diffracted by the diffraction grating plates 410 and 420. Note that the diffraction grating plates 410 and 420 of the displacement detection apparatus correspond to the scales 102a to 102d (scale plate 102) of the measurement apparatus 100. Note also that other constituent members (diffraction grating plate 420, diffraction gratings 422a to 422e, light source 442, light-receiving devices 444b to 444e, and lens 460) correspond to the sensors 104a to 104d of the measurement apparatus 100.

The measurement apparatus 100 according to this embodiment also includes detection units 130 which detect shift amounts (i.e., the positions in the X-Y plane) of the scales 102a to 102d from reference positions when the scales 102a to 102d (scale plate 102) have been chucked by vacuum suction, as shown in FIG. 5. The shift amounts of the scales 102a to 102d from the reference positions include shift components in the X- and Y-axis directions and rotation components about the X- and Y-axes.

In this embodiment, the detection units 130 include reference marks 132 formed on the respective scales 102a to 102d, and measurement units (scopes) 134 which measure the positions of the respective reference marks 132. The reference marks 132 each include, for example, marks X1 to X4 for detecting shift amounts in the X-axis direction, and marks Y1 to Y4 for detecting shift amounts in the Y-axis direction, as shown in FIG. 6. Although the reference marks 132 are formed on the scales 102a to 102d in this embodiment, they may be formed on the scale plate 102. The measurement units 134 each include, e.g., a light source 134a, half mirror 134b, image sensing device 134c, and processing unit 134d. The measurement units 134 are disposed such that their origins are aligned with (the centers of) the reference marks 132 when the scales 102a to 102d are located at predetermined positions (i.e., positions that are not shifted from the reference positions).

In each detection unit 130, light from the light source 134a is reflected by the half mirror 134b and illuminates the reference mark 132 formed on each of the scales 102a to 102d. The light reflected by the reference mark 132 is transmitted through the half mirror 134b and sensed by the image sensing device 134c. The processing unit 134d processes the image signal from the image sensing device 134c to measure the position of the reference mark 132. Based on the thus measured position of the reference mark 132, each detection unit 130 detects a shift amount of a corresponding one of the scales 102a to 102d from the reference position.

The detection unit 130 is not limited to the arrangement shown in FIG. 5, and may include, for example, an interferometer and encoder. The detection unit 130 can also be configured to detect shift amounts not only in the X- and Y-axis directions but also in the Z-axis direction and the rotation directions about the X-, Y-, and Z-axes.

The shift amounts of the scales 102a to 102d from the reference positions, which are detected by the detection units 130, are stored in the storage unit 72 in this embodiment. Note that the storage unit 72 stores a shift AX in the X-axis direction, a shift ΔY in the Y-axis direction, and a rotation angle θ about the Z-axis with respect to the X- and Y-coordinates of the reference position as the shift amount of each of the scales 102a to 102d.

Based on the shift amounts of the scales 102a to 102d from the reference positions, which are stored in the storage unit 72, the calculation unit 74 corrects the position of the wafer stage 45 measured by reading the scales 102a to 102d by the sensors 104a to 104d. If the measurement apparatus 100 has an origin and can measure the absolute position of the wafer stage 45, ΔX, ΔY, and e need to be corrected for the position of the wafer stage 45 measured by reading the scales 102a to 102d by the sensors 104a to 104d. In contrast, if the measurement apparatus 100 measures the relative position of the wafer stage 45, only θ need be corrected for the position of the wafer stage 45 measured by reading the scales 102a to 102d by the sensors 104a to 104d. In this manner, the measurement apparatus 100 can measure the position of the wafer stage 45 with high accuracy by correcting, the position of the wafer stage 45 measured by reading the scales by the sensors, based on the shift amounts of the scales from the reference positions.

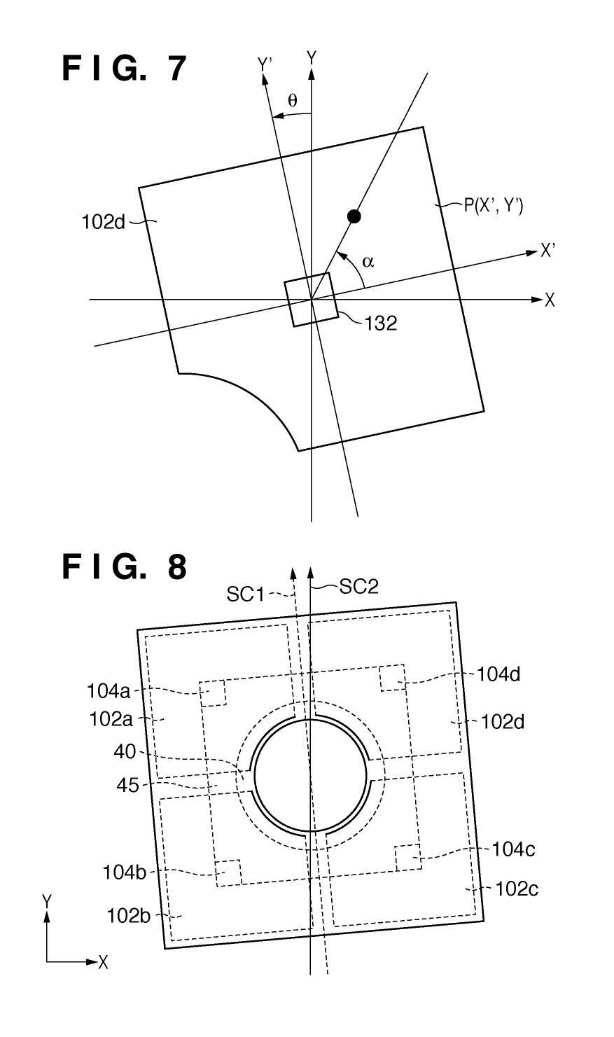

A case in which the position of the wafer stage 45 is measured by reading the scale 102d rotated (i.e., ΔX=0, ΔY=0) through θ with respect to the X- and Y-coordinates of the reference position, as shown in FIG. 7, will be considered. The coordinates rotated through e with respect to the X- and Y-coordinates of the reference position are defined as the X′- and Y′-coordinates. When the position of a point P on a line which forms an arbitrary angle α with the X′-axis in the X′-Y′ coordinate system is measured by reading the scale 102d by an arbitrary sensor, the calculation unit 74 can correct the measured position (X′, Y′) of the point P in accordance with:

X=\sqrt{X′²+Y′²}×cos (α+θ) (1)

Y=\sqrt{X′²+Y′²}×sin (α+θ) (2)

A case in which all the scales 102a to 102d are rotated through θ with respect to the X- and Y-coordinates of the reference positions, as shown in FIG. 8, will be considered herein. Then, using intact the position of the wafer stage 45 measured by reading the scales by the sensors (i.e., without correcting it by the calculation unit 74), the position of the wafer stage 45 is controlled to move the wafer stage 45 in the Y-axis direction. In this case, the moving track of the wafer stage 45 is indicated by an arrow SC1 and this means that the wafer stage 45 moves while being tilted with respect to the Y-axis direction. On the other hand, the calculation unit 74 corrects the position of the wafer stage 45 measured by reading the scales by the sensors, and the position of the wafer stage 45 is controlled based on the corrected position to move the wafer stage 45 in the Y-axis direction, as described above. In this case, the moving track of the wafer stage 45 is indicated by an arrow SC2 and this means that the wafer stage 45 can move in the Y-axis direction.

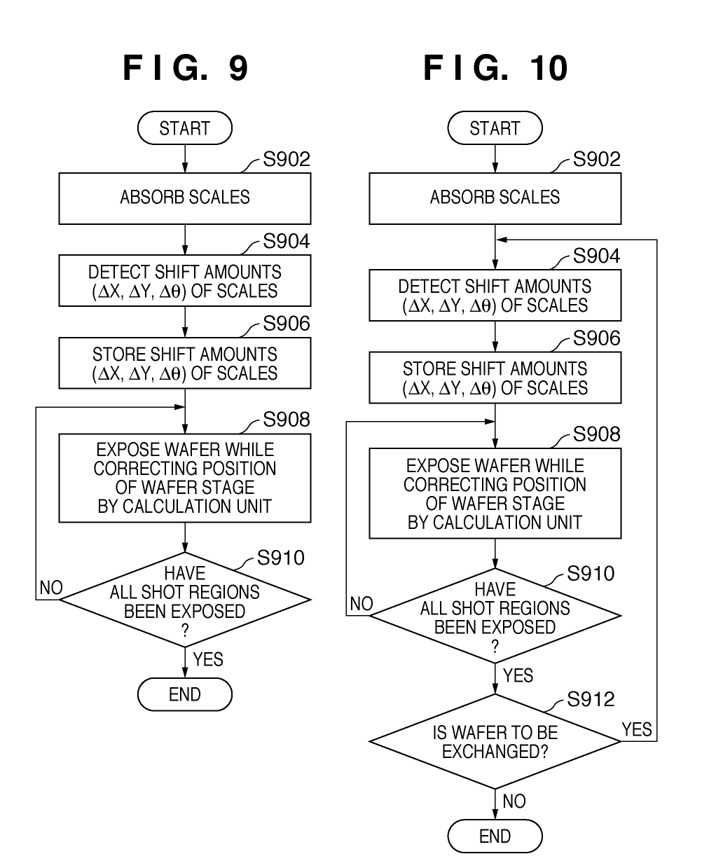

The operation of the exposure apparatus 1 will be explained with reference to FIG. 9. This operation is performed by systematically controlling each unit of the exposure apparatus 1 by the control unit 70.

In step S902, the four scales 102a to 102d (the scale plate 102 which mounts the scales 102a to 102d) are chucked (absorbed) (chucked by, e.g., vacuum suction or magnetic attraction) by the reference frame 50. In step S904, shift amounts (ΔX, ΔY, Δθ) of the scales 102a to 102d from the reference positions when they have been chucked by the reference frame 50 are detected via the detection unit 130. In step S906, the shift amounts (ΔX, ΔY, Δθ) of the scales 102a to 102d detected in step S904 are stored in the storage unit 72. In step S908, the wafer 40 is exposed (the pattern of the reticle 20 is formed on the wafer 40). More specifically, the wafer 40 is exposed by controlling the position of the wafer stage 45 while correcting the position of the wafer stage 45, measured by reading the scales 102a to 102d by the sensors 104a to 104d, by the calculation unit 74 based on the shift amounts of the scales stored in the storage unit 72. Note that the control of the position of the wafer stage 45 includes, e.g., control for moving each shot region on the wafer 40 to the imaging position (target position) of the projection optical system 30, and control for scanning the wafer 40 during exposure. In step S910, it is determined whether all shot regions on the wafer 40 have been exposed. If not all shot regions have been exposed, the process returns to step S908, in which the exposure continues. If all shot regions have been exposed, the operation ends.

In this manner, the exposure apparatus 1 corrects, the position of the wafer stage 45 measured by reading the scales by the sensors, based on the shift amounts of the scales from the reference positions, and exposes the wafer 40 while controlling the position of the wafer stage 45 based on the corrected position. Hence, the exposure apparatus 1 can provide high-quality devices (e.g., a semiconductor device, an LCD device, an image sensing device (e.g., a CCD), and a thin-film magnetic head) with a high throughput and good economical efficiency by preventing changes in the coordinates and running characteristics of the stage. These devices are fabricated by a step of exposing a substrate (e.g., a wafer or a glass plate) coated with a photoresist (photosensitive agent) using the exposure apparatus 1, a step of developing the exposed substrate, and subsequent known steps.

Referring to FIG. 9, shift amounts of the scales 102a to 102d from the reference positions are detected when they have been chucked by the reference frame 50. However, the positions of the scales 102a to 102d (the position of the scale plate 102 which mounts the scales 102a to 102d) may vary due to the influence of, e.g., heat or vibration. In view of this, the position of the wafer stage 45 measured by reading the scales by the sensors can be corrected with higher accuracy by detecting shift amounts of the scales from the reference positions for each shot, each wafer, or each lot, or in real time. If, for example, shift amounts of the scales from the reference positions are detected for each wafer, it is determined whether to exchange the wafer 40 (S912) after step S910, as shown in FIG. 10. If the wafer 40 is exchanged, the process returns to step S904, in which shift amounts of the scales 102a to 102d from the reference positions are detected. If the wafer 40 is not exchanged, the operation ends. Note that if the wafer 40 is not exchanged, the same wafer 40 can be further exposed (i.e., the process returns to step S908, in which the next pattern can be transferred onto the wafer 40 in one example).

Also, in this embodiment, one reference mark 132 and one measurement unit 134 are set for one scale as the detection unit 130 which detects a shift amount of the scale from the reference position. However, a plurality of reference marks 132 and a plurality of measurement units 134 may be set for one scale as the detection unit 130 to detect the two-dimensional positions (shift amounts) of the scale. In this case, the shift amounts of the scale may be averaged and the obtained average may be stored in the storage unit 72, or the shift amount of the scale may be stored in the storage unit 72 for each position.

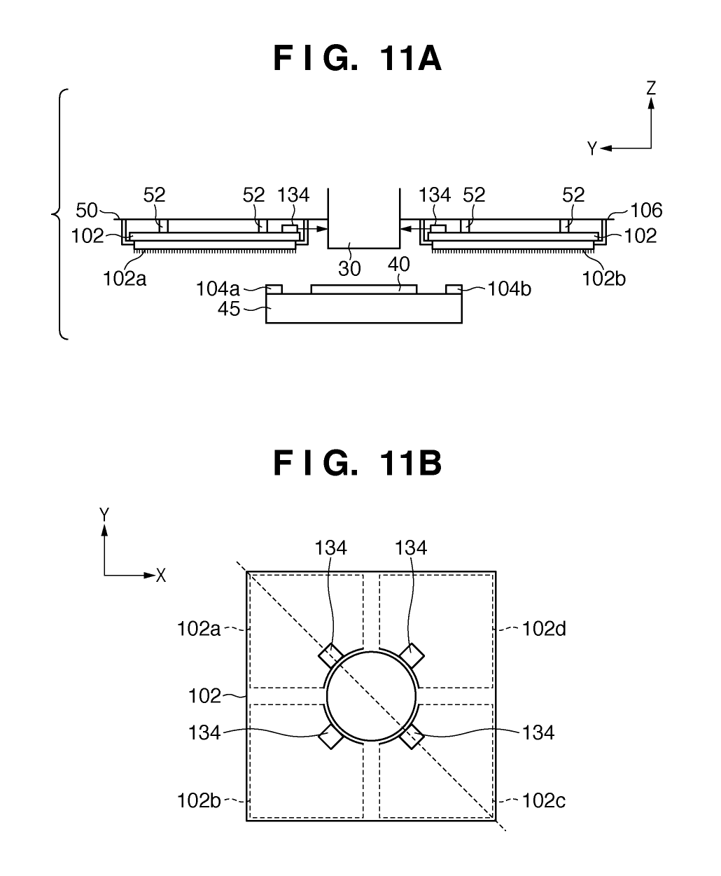

Also, although the detection units 130 detect shift amounts of the scales 102a to 102d from the reference positions by measuring the reference marks 132 formed on the respective scales 102a to 102d in this embodiment, the present invention is not limited to this. For example, measurement units 134 may be set for the respective scales 102a to 102d (scale plate 102) to configure detection units 130 so as to measure the distances between the projection optical system 30 and the respective scales 102a to 102d, as shown in FIGS. 11A and 11B. In this case, the detection units 130 detect shift amounts of the scales 102a to 102d from the reference positions based on the distances between the projection optical system 30 and the respective scales 102a to 102d. Note that FIG. 11A is a sectional view of the measurement apparatus 100 taken along the X-axis direction, and FIG. 11B is a plan view of the scales 102a to 102d when viewed from the Z-axis direction.

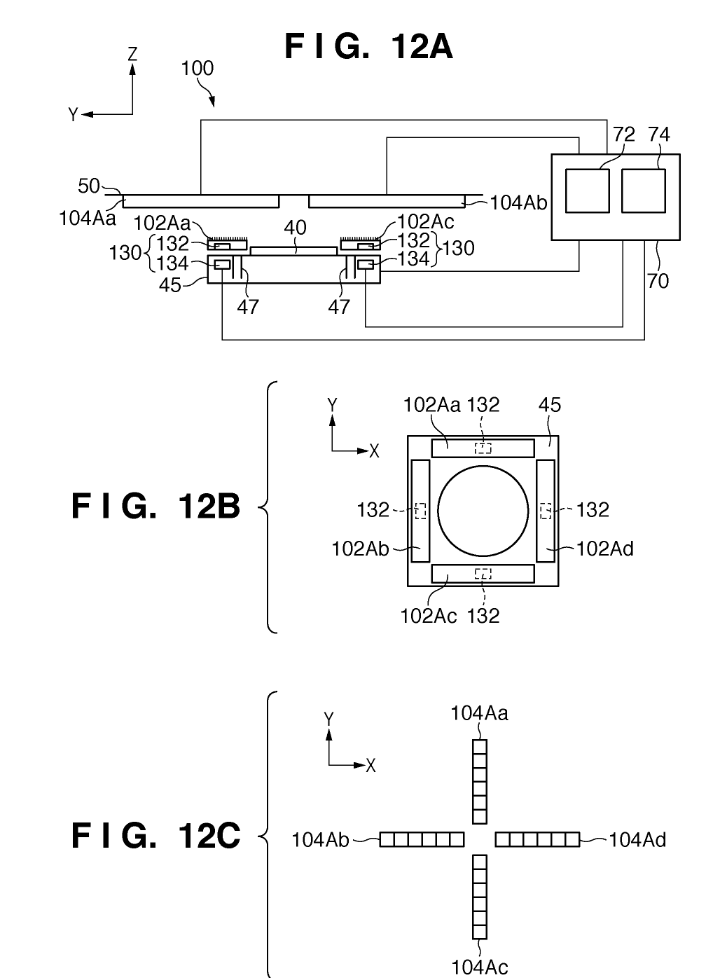

Also, the measurement apparatus 100 may include four scales 102Aa to 102Ad which are detachably attached on the wafer stage 45, and four sensors 104Aa to 104Ad attached on the reference frame 50, as shown in FIGS. 12A to 12C. The scales 102Aa to 102Ad are chucked by vacuum suction by the wafer stage 45 by lowering the pressures in a plurality of grooves 47 formed in the wafer stage 45. However, a scale plate 102 which mounts the scales 102Aa to 102Ad may be chucked by vacuum suction by the wafer stage 45, as described above. The sensors 104Aa to 104Ad are fixed on the reference frame 50. The four scales 102Aa to 102Ad and four sensors 104Aa to 104Ad are arranged such that at least one sensor can read one scale within the moving range of the wafer stage 45. Hence, the measurement apparatus 100 can measure the position of the wafer stage 45 with respect to the reference frame 50 in two axial directions (the X- and Y-axis directions) by reading the scales 102Aa to 102Ad by the sensors 104Aa to 104Ad. In this manner, one of a set of scales and a set of sensors for measuring the position of the target object (wafer stage 45) need only be attached on the target object. Note that FIG. 12A is a sectional view of the measurement apparatus 100 taken along the X-axis direction, FIG. 12B is a plan view of the scales 102Aa to 102Ad when viewed from the Z-axis direction, and FIG. 12C is a plan view of the sensors 104Aa to 104Ad when viewed from the Z-axis direction.

The arrangement shown in FIGS. 12A to 12C includes detection units 130 which detect shift amounts (i.e., the positions in the X-Y plane) of the scales 102Aa to 102Ad when the scales 102Aa to 102Ad have been chucked by vacuum suction, like the foregoing arrangement. More specifically, detection units 130 include reference marks 132 formed on the respective scales 102Aa to 102Ad, and measurement units 134 which are mounted on the wafer stage 45 and measure the positions of the respective reference marks 132. The detection units 130 detect shift amounts of the respective scales 102Aa to 102Ad from the reference positions and the calculation unit 74 corrects the position of the wafer stage 45 measured by reading the scales by the sensors, in the same way as described above.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-094366 filed on Apr. 8, 2009, which is hereby incorporated by reference herein in its entirety.

What is claimed is:

1. A measurement apparatus which includes a scale and a sensor one of which is attached on a target object, and measures a position of the target object by reading the scale by the sensor, the apparatus comprising:
a detection unit configured to detect a shift amount of the scale from a reference position; and
a calculation unit configured to correct, the position of the target object measured by reading the scale by the sensor, based on the shift amount of the scale from the reference position, which is detected by the detection unit.

2. The apparatus according to claim 1, wherein
the detection unit includes
a reference mark formed on the scale, and
a measurement unit configured to measure a position of the reference mark, and
the detection unit detects the shift amount of the scale from the reference position based on the position of the reference mark measured by the measurement unit.

3. The apparatus according to claim 1, wherein the detection unit includes one of an interferometer and an encoder.

4. The apparatus according to claim 1, wherein
the scale is detachably attached on a structure which faces the target object, and
the sensor is attached on the target object.

5. The apparatus according to claim 1, wherein
the scale is detachably attached on the target object, and
the sensor is attached on a structure which faces the target object.

6. An exposure apparatus including a projection optical system which projects a pattern of a reticle onto a substrate, the apparatus comprising:
a stage configured to hold the substrate;
a measurement apparatus which includes a scale and a sensor one of which is attached on the stage, and is configured to measure a position of the stage by reading the scale by the sensor; and
a control unit configured to control the position of the stage,
the measurement apparatus including:
a detection unit configured to detect a shift amount of the scale from a reference position; and
a calculation unit configured to correct, the position of the stage measured by reading the scale by the sensor, based on the shift amount of the scale from the reference position, which is detected by the detection unit,
wherein the control unit controls the position of the stage based on the position of the stage corrected by the calculation unit.

7. The apparatus according to claim 6, wherein
the scale is detachably attached on a structure which faces the stage,
the detection unit includes a measurement unit which is fixed with respect to the scale and is configured to measure a distance between the detection unit and the projection optical system, and
the detection unit detects the shift amount of the scale from the reference position based on the distance measured by the measurement unit.

8. A device fabrication method comprising steps of:
exposing a substrate using an exposure apparatus; and
performing a development process for the substrate exposed,
wherein the exposure apparatus includes:
a stage configured to hold the substrate;
a measurement apparatus which includes a scale and a sensor one of which is attached on the stage, and is configured to measure a position of the stage by reading the scale by the sensor; and
a control unit configured to control the position of the stage,
the measurement apparatus including:
a detection unit configured to detect a shift amount of the scale from a reference position; and
a calculation unit configured to correct, the position of the stage measured by reading the scale by the sensor, based on the shift amount of the scale from the reference position, which is detected by the detection unit,
wherein the control unit controls the position of the stage based on the position of the stage corrected by the calculation unit.
